(19) United States
(12) Patent Application Publication
(10) Pub. No.: US 2012/0091516 A1
(43) Pub. Date: Apr. 19, 2012

(54) Lateral Floating Coupled Capacitor Device Termination Structures

(76) Inventors: Robert Kuo-Chang Yang, Campbell, CA (US); Sunglyong Kim, South Portland, ME (US); Joseph A. Yedinak, Mountain Top, PA (US)

(21) Appl. No.: 13/084,437

(22) Filed: Apr. 11, 2011

Related U.S. Application Data
(60) Provisional application No. 61/324,587, filed on Apr. 15, 2010.

(51) Int. Cl. H01L 27/06; H01L 29/06

(52) U.S. Cl. 257/296; 257/487; 257/E27.016; 257/E29.007

(57) ABSTRACT

Voltage termination structures include one or more capacitively coupled trenches, which can be similar to the trenches in the drift regions of the active transistor. The capacitively coupled trenches in the termination regions are arranged with an orientation that is either parallel or perpendicular to the trenches in the active device drift region. The Voltage termination structures can also include capacitively segmented trench structures having dielectric lined regions filled with conducting material and completely surrounded by a silicon mesa region. The Voltage termination structures can further include continuous regions composed entirely of an electrically insulating layer extending a finite distance vertically from the device surface.

### CROSS-REFERENCE TO RELATED APPLICATIONS

This application claims the benefit of U.S. Provisional Application No. 61/324,587, filed Apr. 15, 2010, which is incorporated herein by reference in its entirety for all purposes.

### BACKGROUND

In semiconductor devices, including high voltage devices, it is desirable to obtain a low on-resistance that is primarily determined by the drift region resistance. Typically, the drift region resistance of a transistor is lowered by increasing the doping level of the drift region. However, increasing the doping level of the drift region has the undesirable effect of reducing the breakdown voltage. The doping level of the drift region is therefore optimized to obtain the maximum on-resistance while still maintaining a sufficiently high breakdown voltage. As the requirements for breakdown voltages increase, the use of drift region doping concentrations to adjust on-resistance and breakdown voltages becomes more difficult.

In addition to breakdown voltages being affected by the doping concentration of the drift region, breakdown voltages are also affected by the electric field distribution inside and outside the active device. As a result, there have been efforts in the art to control the electric field distribution by field-shaping methods and therefore control the on-resistance and breakdown voltage of transistor devices. For example, lateral floating coupled capacitor (LFCC) structures have been used to control the electric fields in the drift region of a transistor and thereby improve on-resistance. These LFCC structures include insulated trenches formed in the drift region of a transistor, which contain isolated electrodes and are parallel to the direction of current flow. These LFCC structures improve transistor properties. For example, the drift region field-shaping provided by the LFCC regions can desirably provide high breakdown voltage and low on-resistance simultaneously. However, when sustaining source to drain voltages up to 700 volts, breakdown can occur at the ends and edges of the active transistor region. It is known in the art that termination regions which surround active device regions preferably have a breakdown voltage higher than that of active device region, to prevent premature breakdown at the ends and edges of the active region.

Therefore there is a need for an improved LFCC semiconductor device that has higher termination breakdown voltage by using similar LFCC structure in the termination region without introducing extra steps in the process flow.

### BRIEF SUMMARY

Embodiments of the present invention provide a series of termination structures that prevent the premature breakdown of the LFCC device at the edges or ends. The LFCC device has voltage termination structures with one or more capacitively coupled trenches, which can be similar to the trenches in the drift regions of the active transistor. The capacitively coupled trenches in the termination regions are arranged with an orientation that is either parallel or perpendicular to the trenches in the active device drift region. Embodiments also provide for capacitively segmented trench structures having dielectric lined regions filled with conducting material and completely surrounded by a silicon mesa region. Embodiments further provide for continuous regions composed entirely of an electrically insulating layer extending a finite distance vertically from the device surface.

In one embodiment, a semiconductor device includes an active region including a plurality of capacitively coupled active trenches arranged parallel to each other along a first direction, and a voltage termination structure including at least one capacitively coupled termination trench arranged along a second direction. The second direction is perpendicular to the first direction.

In another embodiment, the active trenches and the termination trenches are substantially similar.

In yet another embodiment, the at least one termination pitch (trench+mesa) includes silicon regions that are either wider or narrower laterally from capacitor to capacitor than those used for conduction in the active device drift regions.

In yet another embodiment, the at least one termination pitch includes first silicon regions that are half the width from capacitor to capacitor than second silicon regions used for conduction in the active device drift regions.

In yet another embodiment, the at least one termination pitch includes first silicon regions that are shorter or longer in a direction parallel to the termination trenches than second silicon regions used for conduction in the active device drift regions.

In yet another embodiment, the at least one termination pitch includes first silicon regions that are twice as long in a direction parallel to the termination trenches than second silicon regions used for conduction in the active device drift regions.

In yet another embodiment, the at least one termination pitch includes first silicon regions that are doped differently, either higher or lower, or with a different dopant species, than second silicon regions used for conduction in the active device drift regions.

In yet another embodiment, the termination structure includes metal field plates disposed at the source side, the drain side, or both sides. The field plates can be fabricated using processes used for forming metal interconnect layers.

In yet another embodiment, the semiconductor device further includes polysilicon connectors, which are disposed over polysilicon field plates that are located in at least one termination trench. The polysilicon connectors can be electrically coupled to at least one polysilicon field plate. The polysilicon connectors can be disposed perpendicular to the at least one termination trench and can have a spacing separating adjacent polysilicon connectors that varies. In one embodiment the spacing gets larger as the polysilicon connectors get closer to the drain side.

In yet another embodiment, the at least one termination pitch includes a transitional silicon mesa disposed between the termination trenches and the conduction trenches. The transitional mesa can be the same width, wider, or narrower than the conduction mesas.

In yet another embodiment, the termination structure includes one or more field plates formed by polysilicon, metal, or other conducting material extending from over the conduction trenches to over the termination trenches in a pattern that modifies the electric fields present in the termination trenches.

In another embodiment, a semiconductor device includes an active region including a plurality of capacitively coupled active trenches arranged parallel to each other along a first direction, and a voltage termination structure including at least one capacitively coupled termination trench arranged along a second direction. The second direction is parallel to the first direction.

In yet another embodiment where the termination trenches are parallel to the active trenches, the active trenches and the termination trenches are substantially similar.

In yet another embodiment where the termination trenches are parallel to the active trenches, the at least one termination pitch includes first silicon regions that are either wider or narrower laterally from capacitor to capacitor than second silicon regions used for conduction in the active device drift regions.

In yet another embodiment where the termination trenches are parallel to the active trenches, the at least one termination pitch includes first silicon regions that are half the width from capacitor to capacitor than second silicon regions used for conduction in the active device drift regions.

In yet another embodiment where the termination trenches are parallel to the active trenches, the at least one termination pitch includes first silicon regions that are shorter or longer in a direction parallel to the termination trenches than second silicon regions used for conduction in the active device drift regions.

In yet another embodiment where the termination trenches are parallel to the active trenches, the at least one termination pitch includes first silicon regions that are twice as long in a direction parallel to the termination trenches than second silicon regions used for conduction in the active device drift regions.

In yet another embodiment where the termination trenches are parallel to the active trenches, the at least one termination pitch includes first silicon regions that are doped differently, either higher or lower, or with a different dopant species, than second silicon regions used for conduction in the active device drift regions.

In yet another embodiment where the termination trenches are parallel to the active trenches, the termination structure includes metal field plates at the source side, the drain side, or both sides. The field plates can be fabricated by any or all of the process metal interconnect layers.

In yet another embodiment, the semiconductor device further includes polysilicon connectors disposed over polysilicon field plates. The polysilicon connectors can be electrically coupled to at least one polysilicon field plate, which is disposed in at least one termination trench. The polysilicon connectors can be disposed perpendicular to the at least one termination trench and can have a spacing separating adjacent polysilicon connectors that varies. In one embodiment the spacing gets larger as the polysilicon connectors get closer to the drain side.

In yet another embodiment where the termination trenches are parallel to the active trenches, the at least one termination pitch includes a transitional silicon mesa between the termination trenches and the conduction trenches. The transitional mesa can be the same width, wider, or narrower than the conduction mesas.

In yet another embodiment where the termination trenches are parallel to the active trenches, the termination structure includes one or more field plates formed by polysilicon, metal, or other conducting material extending from over the conduction trenches to over the termination trenches in a pattern that modifies the electric fields present in the termination trenches.

In another embodiment, a semiconductor device includes an active region including a plurality of capacitively coupled active trenches arranged parallel to each other along a first direction, and a voltage termination structure including at least one capacitively segmented trench structure having dielectric lined regions filled with conducting material and completely surrounded by a silicon mesa region.

In yet another embodiment, the at least one termination trench includes a width to length aspect ratio of about one.

In yet another embodiment, the at least one termination trench includes a width that is substantially the same, or wider, or narrower than the intrinsic device conduction trenches.

In yet another embodiment, the at least one termination trench shares one or more processing steps with the intrinsic device drain drift region conduction trenches.

In yet another embodiment, the at least one termination pitch includes first silicon regions doped differently, either higher or lower, or with a different dopant species, than second silicon regions used for conduction in the active device drift regions.

In yet another embodiment, the termination structure includes metal field plates at the source side, the drain side, or both sides and at least one termination trench which includes at least one polysilicon field plate. The semiconductor device can further include polysilicon connectors disposed over the polysilicon field plates. The polysilicon connectors can be electrically coupled to at least one polysilicon field plate. The polysilicon connectors can be disposed perpendicular to the at least one termination trench and can have a spacing separating adjacent polysilicon connectors that varies. In one embodiment the spacing gets larger as the polysilicon connectors get closer to the drain side.

In yet another embodiment, the at least one termination pitch includes a transitional silicon mesa between the termination trenches and the conduction trenches. The transitional mesa can be the same width, wider, or narrower than the conduction mesas.

In another embodiment, a semiconductor device includes an active region including a plurality of capacitively coupled active trenches arranged parallel to each other along a first direction, and a voltage termination structure including a continuous termination region composed entirely of an electrically insulating layer extending a finite distance vertically from the device surface.

In yet another embodiment, the insulating layer includes deposited silicon dioxide.

In yet another embodiment, the insulating layer includes thermally grown silicon dioxide.

In yet another embodiment, the insulating layer includes deposited silicon nitride.

In yet another embodiment, the insulating layer includes thermally grown silicon nitride.

Further areas of applicability of the present disclosure will become apparent from the detailed description provided hereinafter. It should be understood that the detailed description and specific examples, while indicating various embodiments, are intended for purposes of illustration only and are not intended to necessarily limit the scope of the disclosure.

### BRIEF DESCRIPTION OF THE DRAWINGS

A further understanding of the nature and advantages of the invention may be realized by reference to the remaining portions of the specification and the drawings, presented below. The Figures are incorporated into the detailed description portion of the invention.

FIG. 1A is a top view of a semiconductor device 100 having a lateral floating coupled capacitor device (LFCC) termination structure.

FIG. 1B is an illustrations showing a cross-section of the semiconductor device 100 showing an active LFCC trench.

FIG. 2 is an illustration showing a top view of a semiconductor device having a perpendicular termination structure.

FIG. 3 is an illustration showing a top view of a semiconductor device having a parallel termination structure.

FIG. 4 is an illustration showing a top view of a semiconductor device having a parallel termination structure with M1/M2 field plates.

FIG. 5 is an illustration showing a top view of a semiconductor device having a parallel termination structure with half transition spacing.

FIG. 6A is an illustration showing a semiconductor device with polysilicon field plates that extend from an active area to a termination area to modify the electric field in the termination trenches.

FIG. 6B is an exploded view of the region labeled 6B in FIG. 6A.

FIG. 7 is an illustration showing a semiconductor device with a voltage termination structure having one or more capacitively segmented trench structures.

FIG. 8 is an illustration showing a semiconductor device with a voltage termination structure having a continuous termination region composed entirely of an electrically insulating layer extending a finite distance vertically from the device surface.

FIG. 9A is an illustration showing a semiconductor device having a voltage termination structure that is perpendicular to the active region and has polysilicon-connections, which are equally spaced, in accordance with an embodiment.

FIG. 9B is an illustration showing a semiconductor device having a termination structure that is perpendicular to the active region and has wider polysilicon-connection to polysilicon-connection spacing between polysilicon-connections towards the drain finger tip, in accordance with an embodiment.

### DETAILED DESCRIPTION

In the following description, for the purposes of explanation, specific details are set forth in order to provide a thorough understanding of the invention. However, it will be apparent that the invention may be practiced without these specific details.

Embodiments of the present invention provide voltage termination structures having one or more capacitively coupled trenches, which can be similar to the trenches in the drift regions of the active transistor. The capacitively coupled trenches in the termination regions are arranged with an orientation that is either parallel or perpendicular to the trenches in the active device drift region. Embodiments also provide for capacitively segmented trench structures having dielectric lined regions filled with conducting material and completely surrounded by a silicon mesa region. Embodiments further provide for continuous region composed entirely of an electrically insulating layer extending a finite distance vertically from the device surface.

Embodiments also provide for polysilicon connectors disposed over polysilicon field plates, which are disposed in the termination trenches. The polysilicon connectors can be electrically coupled to at least one polysilicon field plate. The polysilicon connectors can be disposed perpendicular to the at least one termination trench and can have a spacing separating adjacent polysilicon connectors that varies. In some embodiments the spacing gets larger as the polysilicon connectors get closer to the drain side.

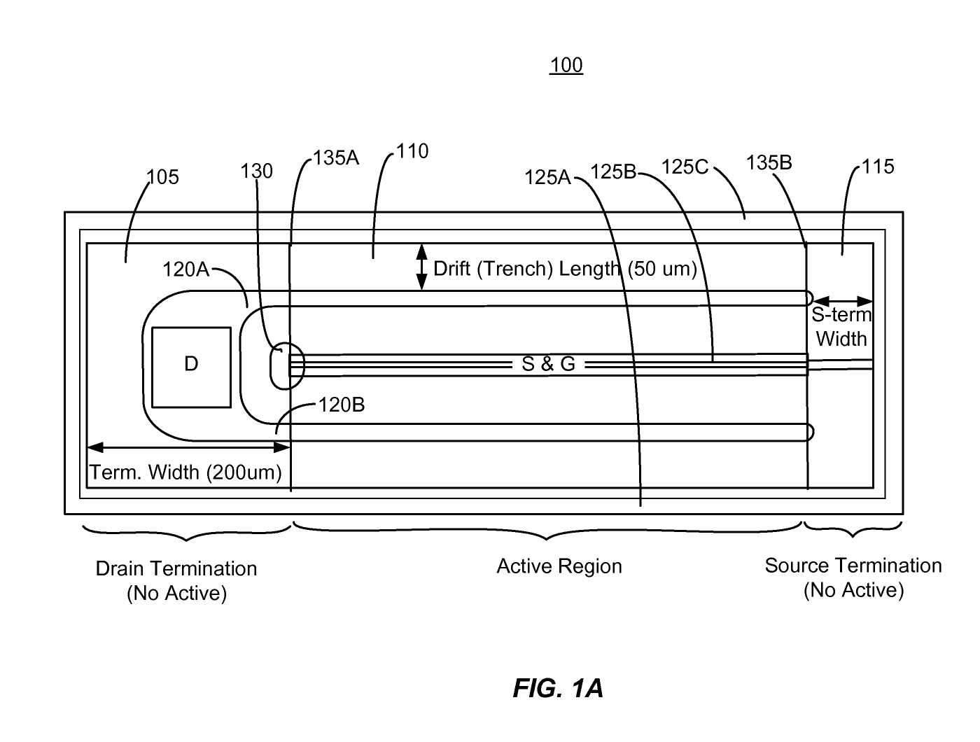

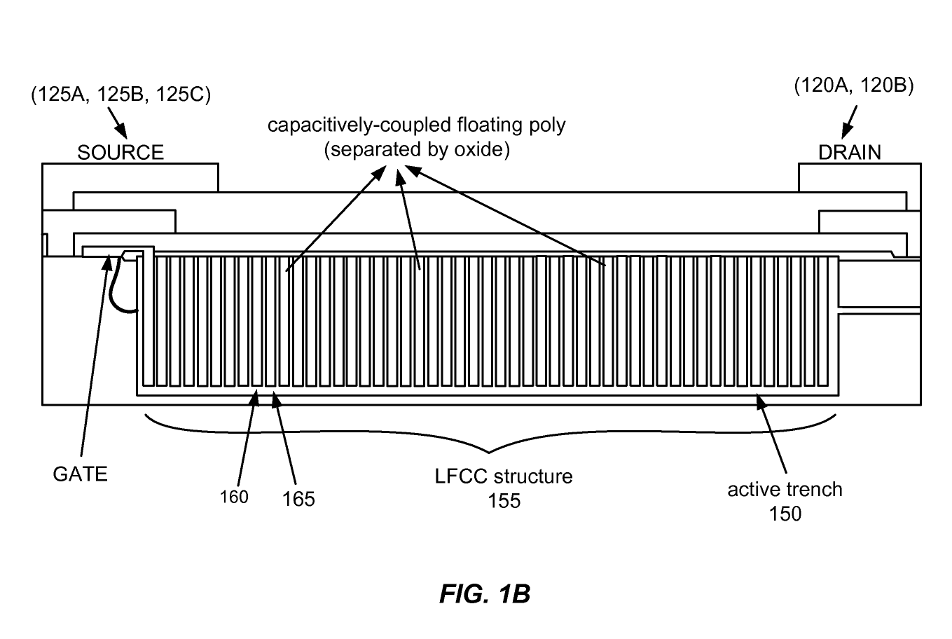

FIG. 1A is a top view of a semiconductor device 100 having an LFCC termination structure including a drain termination region 105, an active region 110 and a source termination region 115. In the embodiment illustrated, the semiconductor device 100 includes two drains (120A and 120B), which are electrically connected together, and three source fingers (125A, 125B, and 125C), which are also electrically connected together. One source finger can be a source finger tip 130, as illustrated. The drain termination region 105 is separated from the active region 110 by a first transition region 135A and the active region 110 is separated from the source region 115 by a second transition region 135B. The active area 110 includes drift trenches and the termination region 105 includes termination trenches. In one embodiment the size of the semiconductor device 100 is 0.2 mm² (800 um×250 um), the length of the drift trenches is 50 um and the width of the drain termination is 200 um. In one embodiment, the total width of the source termination (S-term) 115 is at least 2× times the drift length of the active region 110. In some embodiments the termination region 105 is configured so that the highest voltage potential is near the drains (120A and 120B) and the lowest voltage potential is near the edge of the termination structure 105, which is furthest away from the drains (120A and 120B). The transition from the highest voltage potential to the lowest voltage potential can be gradual.

FIG. 1B is an illustration showing a cross-section of the semiconductor device 100 including an active LFCC trench 150 with an LFCC structure 155 disposed inside the trench 150. The LFCC trench includes capacitively coupled floating conductors 160 separated by a dielectric 165. In one embodiment, the capacitively coupled floating conductors 160 are polysilicon and the dielectric 165 is oxide. The source fingers (125A, 125B, 125C) are illustrated as being electrically connected to the gate. The drain (120A, 120B) is disposed next to the active LFCC trench 150 and on the opposite side of the LFCC trench 150 as the source fingers (125A, 125B, 125C) and gate.

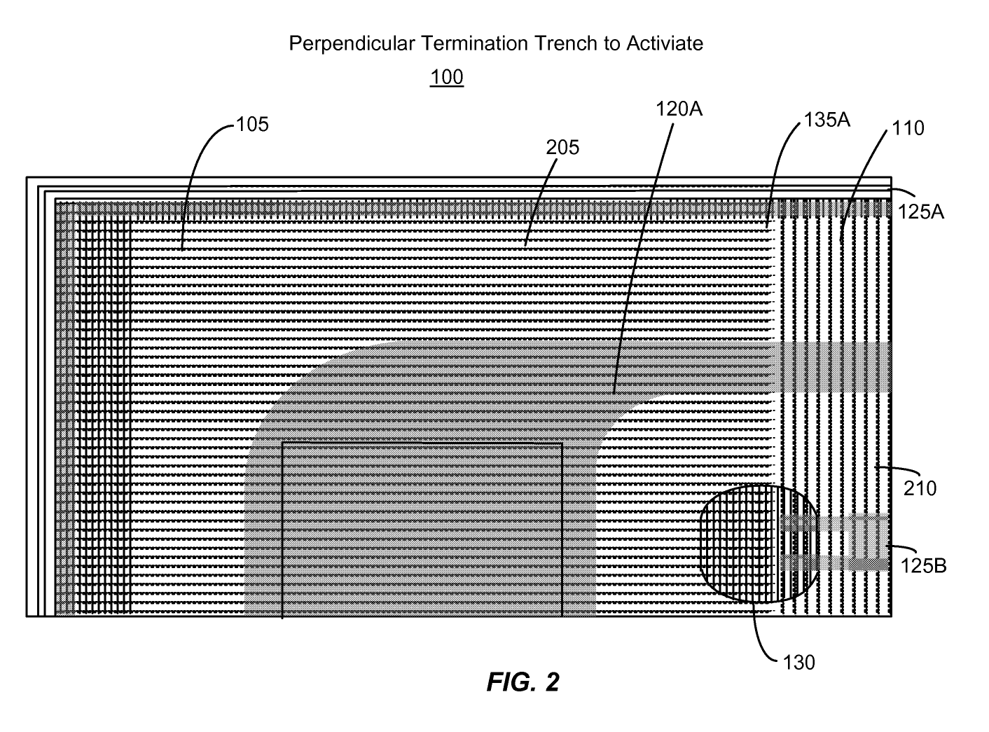

FIG. 2 is an illustration showing an exploded top view of an embodiment of the semiconductor device 100 having termination trenches 205 located in the drain termination region 105 that are perpendicular to the active trenches 210 located in the active region 110. In one embodiment, the semiconductor device 100 includes an active region 110 including a plurality of capacitively coupled active trenches 210 arranged parallel to each other along a first direction, and a voltage termination structure 105 including at least one capacitively coupled termination trench 205 arranged along a second direction. The second direction is perpendicular to the first direction. The active trenches 210 and the termination trenches 205 can be substantially similar.

In an embodiment, the at least one termination pitch (termination trench 205+spacing between termination trench 205) includes silicon regions that are either wider or narrower laterally from capacitor to capacitor than those used for conduction in the active device 110 drift regions. The at least one termination pitch can also include first silicon regions that are half the width from capacitor to capacitor than second silicon regions used for conduction in the active device 110 drift regions. The at least one termination pitch can include first silicon regions that are shorter or longer in a direction parallel to the termination trenches than second silicon regions used for conduction in the active device 110 drift regions. The at least one termination pitch can also include first silicon regions that are twice as long in a direction parallel to the termination trenches than second silicon regions used for conduction in the active device 110 drift regions. The at least one termination pitch can further include first silicon regions that are doped differently, either higher or lower, or with a different dopant species, than second silicon regions used for conduction in the active device 110 drift regions.

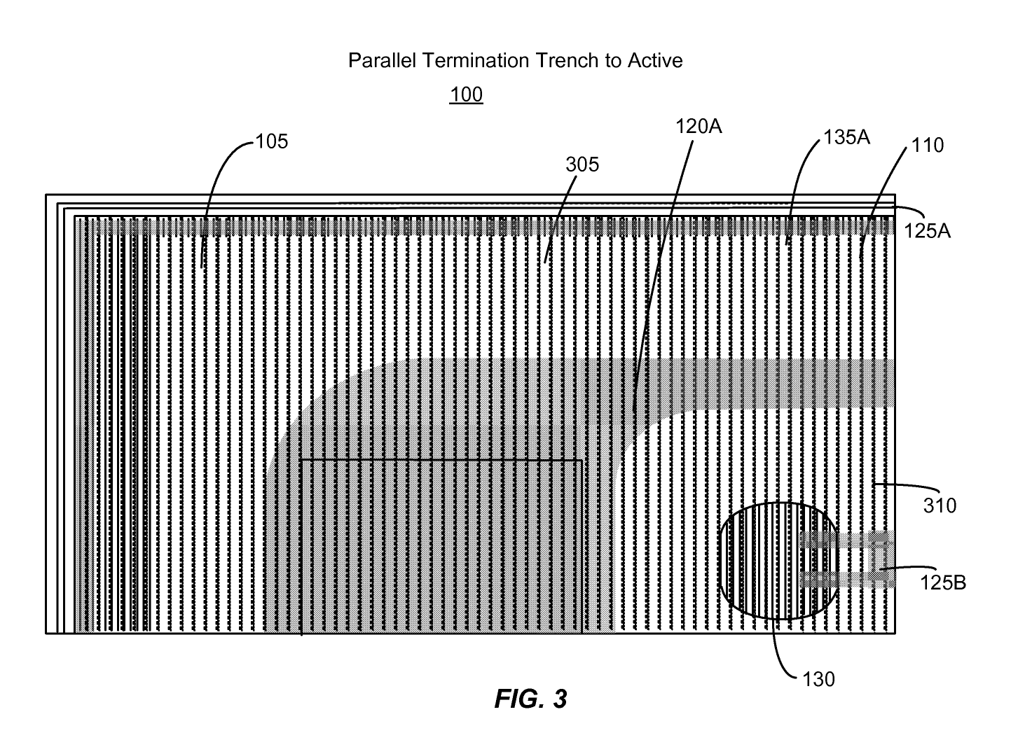

FIG. 3 is an illustration showing an exploded top view of an embodiment of the semiconductor device 100 having termination trenches 305 located in the drain termination region 105 that are parallel to the active trenches 310 located in the active region 110. In one embodiment, the semiconductor device 100 includes an active region 110 including a plurality of capacitively coupled active trenches 310 arranged parallel to each other along a first direction, and a voltage termination structure 105 including at least one capacitively coupled termination trench 305 arranged along a second direction. The second direction is parallel to the first direction. The active trenches 310 and the termination trenches 305 can be substantially similar.

In an embodiment, the at least one termination pitch (termination trench 305+spacing between termination trench 305) includes silicon regions that are either wider or narrower laterally from capacitor to capacitor than those used for conduction in the active device 110 drift regions. The at least one termination pitch can also include first silicon regions that are half the width from capacitor to capacitor than second silicon regions used for conduction in the active device 110 drift regions. The at least one termination pitch can include first silicon regions that are shorter or longer in a direction parallel to the termination trenches than second silicon regions used for conduction in the active device 110 drift regions. The at least one termination pitch can also include first silicon regions that are twice as long in a direction parallel to the termination trenches than second silicon regions used for conduction in the active device 110 drift regions. The at least one termination pitch can further include first silicon regions that are doped differently, either higher or lower, or with a different dopant species, than second silicon regions used for conduction in the active device 110 drift regions.

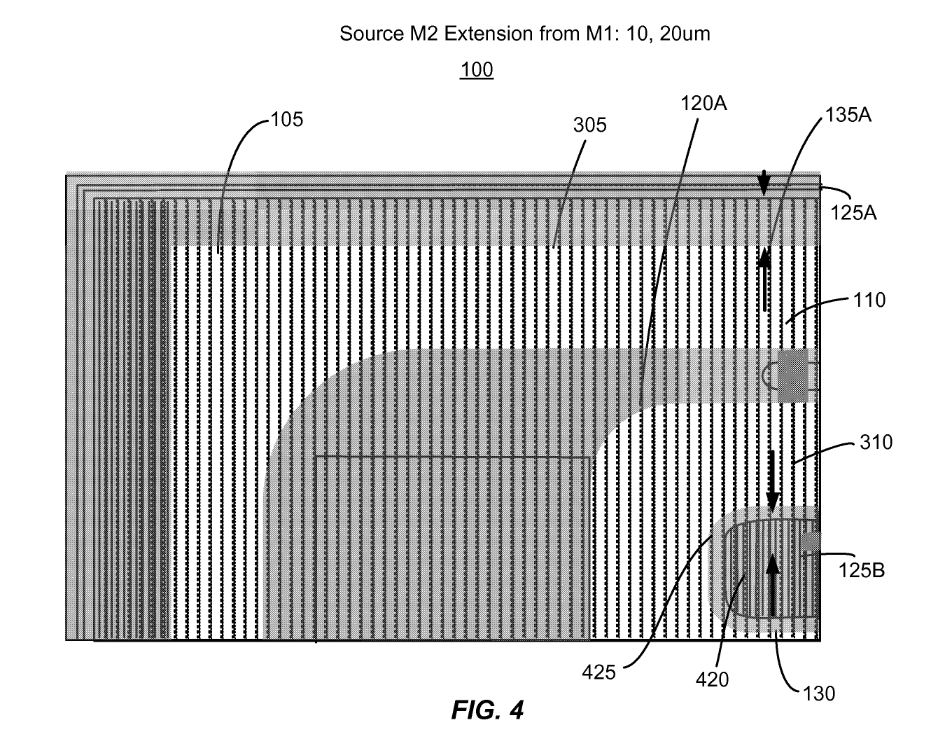

FIG. 4 is an illustration showing an exploded top view of an embodiment of the semiconductor device 100 having metal 1 (M1) field plates 420 and metal 2 (M2) field plates 425. The M1 field plates 420 and M2 field plates 425 are in a semiconductor device 100 that has termination trenches 305 parallel to the active trenches 310. The termination structure includes metal field plates (420 and 425) disposed at the source side, the drain side, or both sides. The field plates (420 and 425) can be fabricated by any or all of the process metal interconnect layers using established design methods. The M1/M2 field plates (420 and 425), which are in the active region 110 and on the end of the source finger 125B, extend 10-20 μm. Multi-tiered field plates using poly, metal 1, and metal 2 with different extension (e.g. increased extension from poly, M1, M2, respectively) can be used to further enhance the effect of field plating on breakdown voltage.

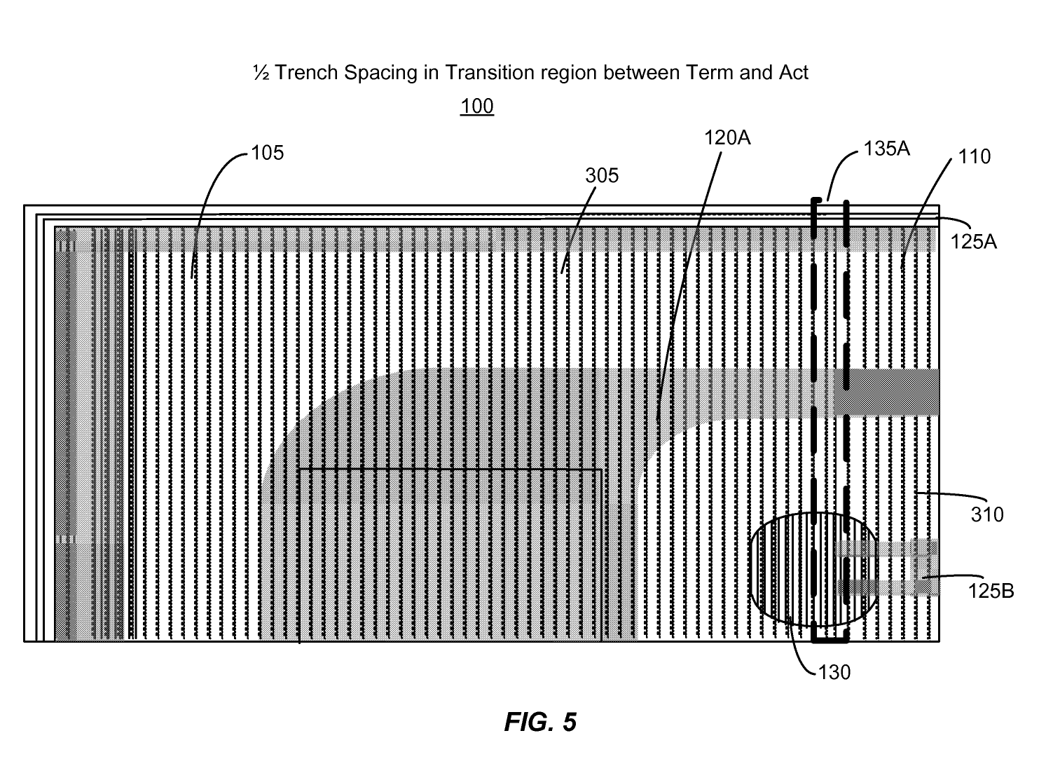

FIG. 5 is an illustration showing an exploded top view of an embodiment of the semiconductor device 100 having a half trench spacing in the first transition region 135A, which separates the termination region 105 and the active region 110. The transition region 135A is illustrated in a semiconductor device 100 that has termination trenches 305 parallel to the active trenches 310. The termination trenches 305 include a transitional silicon mesa located in the transition region 135A between the termination trenches 305 and the conduction active trenches 310. The transitional mesa may be the same width, or wider, or narrower than the conduction active trenches 310.

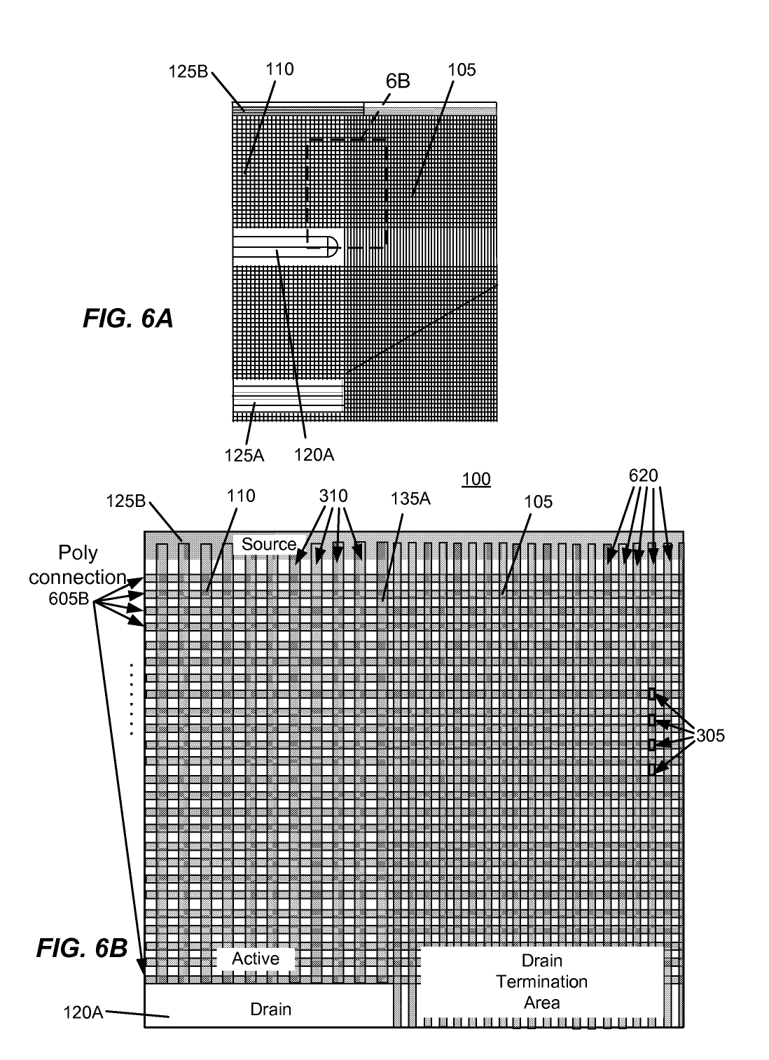

FIG. 6A is an illustration showing a semiconductor device 100 having a termination region 105, an active region 110, source fingers (125A and 125B) and drain finger 120A. The semiconductor device 100 includes polysilicon field plates that extend from an active region 110 to a termination region 105, which are used to modify the electric field in the termination trenches 305, as explained further with reference to FIG. 6B.

FIG. 6B is an exploded view of the region labeled 6B in FIG. 6A. The termination trenches 620 include one or more polysilicon field plates 305. These polysilicon field plates 305 are analogous to floating conductor regions 160 in FIG. 1B.

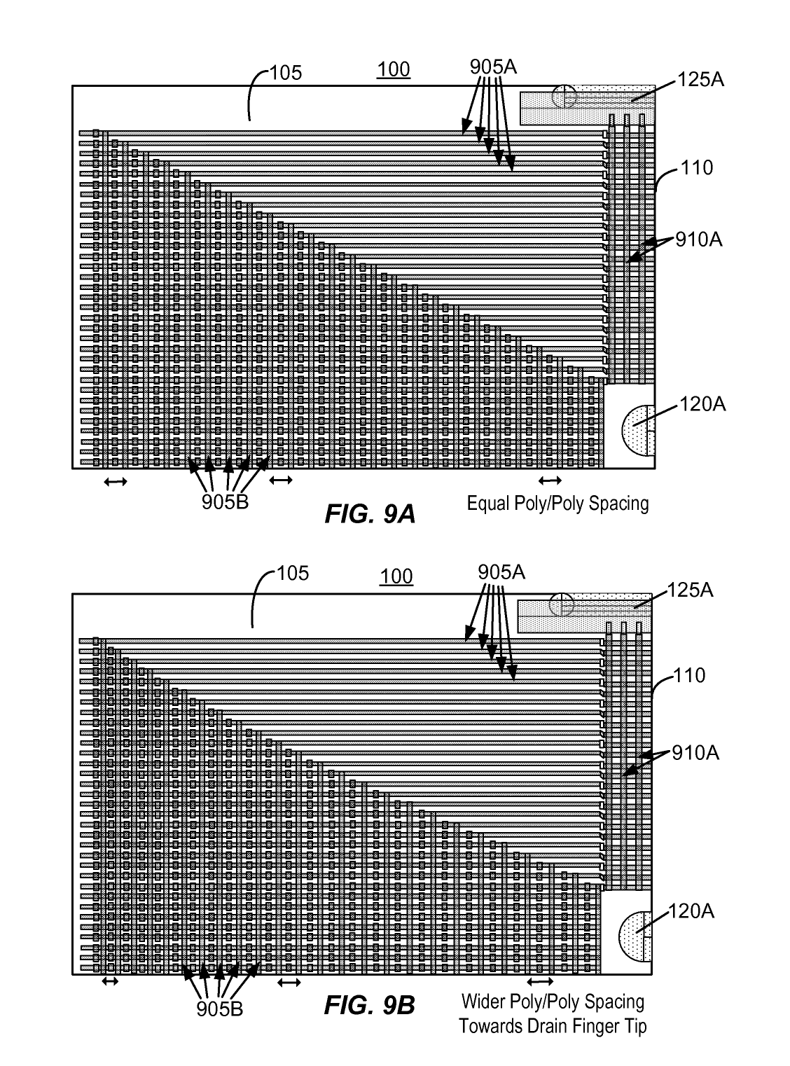

In one embodiment, the polysilicon field plates 305, which are located inside termination trenches 620, are coupled to polysilicon connections 605B which run perpendicular to the termination trenches 620. The polysilicon connections 605B are used to carry over the potential in the active region 110 into termination region 105 with increasing voltage from the source to the drain along the drift region through multiple electrically isolated LFCC regions (not shown). The polysilicon connections 605B run perpendicular to the active trenches 310. Each of the polysilicon connections 605B can overlay all the termination trenches 620, in a perpendicular direction, and make contact with at least one polysilicon field plate 305 disposed in a termination trench 620. Alternatively, each of the polysilicon connections 605B can overlay at least one of the termination trenches 620, in a perpendicular direction, and make contact with at least one polysilicon field plate 305 disposed in an overlaid termination trench 620. In one embodiment, each polysilicon connections 605B is set to make contact with polysilicon field plates 305 located in only a single termination trench 620. The polysilicon connections 605B can be laid out over the termination trenches 620 and polysilicon field plates 305 using various configurations such as those described with reference to FIGS. 9A and 9B below.

Although the embodiments illustrated in FIGS. 4, 5, and 6 are shown for semiconductor devices 100 having termination trenches 305 located in the drain termination region 105 that are parallel to the active trenches 310 located in the active region 110, as illustrated in FIG. 3, those skilled in the art will realize that the invention extends to semiconductor devices 100 having termination trenches 205 located in the drain termination region 105 that are perpendicular to the active trenches 210 located in the active region 110, as illustrated in FIG. 2.

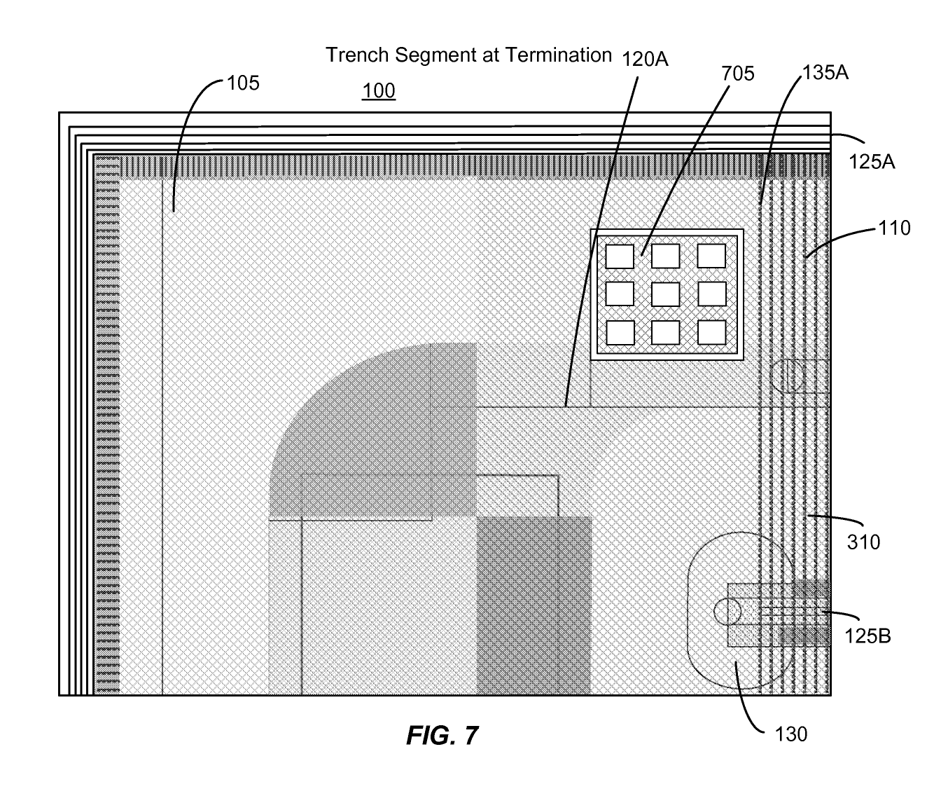

FIG. 7 is an illustration showing an exploded top view of an embodiment of the semiconductor device 100 having a voltage termination structure located in the drain termination region 105 with one or more capacitively segmented trench structures 705. In one embodiment, the semiconductor device 100 includes an active region 110 including a plurality of capacitively coupled active trenches 310 arranged parallel to each other along a first direction, and a voltage termination structure 105 including one or more capacitively segmented trench structures 705 arranged along a second direction. The capacitively segmented trench structures 705 can include trench segments that are approximately 1 μm×1 μm in size. The capacitively segmented trench structures 705 can include dielectric lined regions filled with conducting material and completely surrounded by a silicon mesa region. The termination trenches 705 can include a width to length aspect ratio of about one. At least one termination trenches 705 can have a width that is substantially the same, or wider, or narrower than the intrinsic device conduction trenches. Arrangement of each column segment trench 705 can be aligned (as shown), offset, or staggered, provided the mesa width between segment trenches 705 is kept constant.

The termination pitch (termination trench 705+spacing between termination trench 705) can also include first silicon regions that are doped differently. The first silicon regions can be doped, either higher or lower, or with a different dopant species, than second silicon regions used for conduction in the active device drift regions. The termination structure can also include metal field plates at the source side, the drain side, or both sides. The termination pitch can also include a transitional silicon mesa between the termination trenches and the conduction trenches. The transitional mesa can be the same width, wider, or narrower than the conduction mesas.

The fabrication process of the termination trenches 705 can share one or more processing steps with the intrinsic device drain drift region conduction trenches.

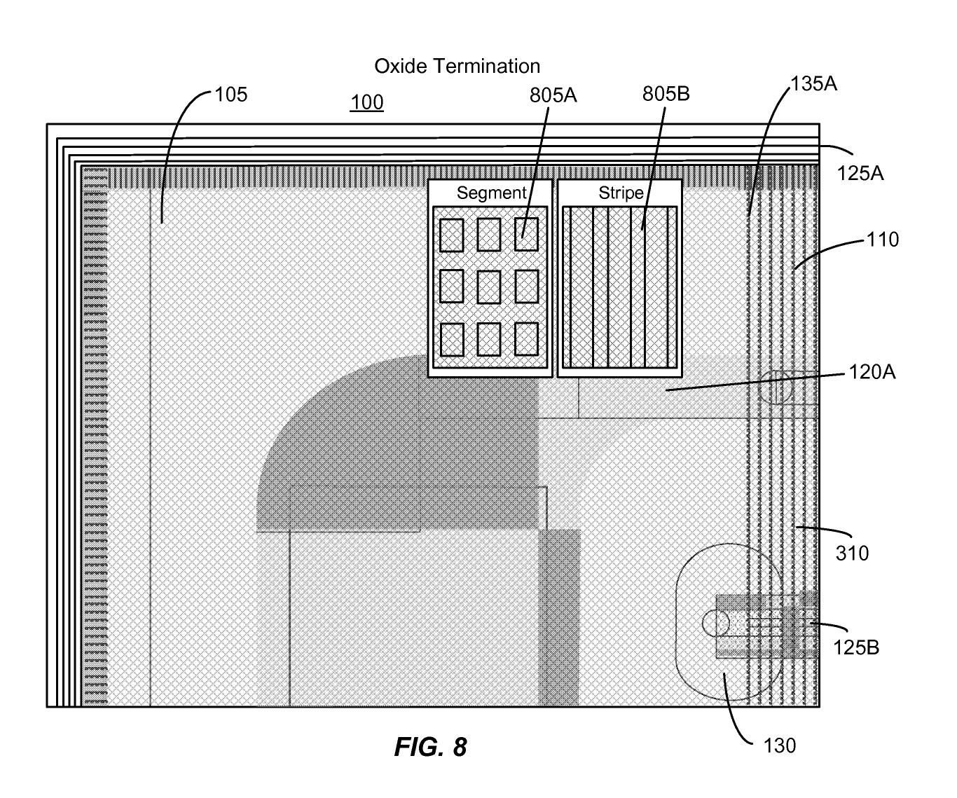

FIG. 8 is an illustration showing an exploded top view of an embodiment of the semiconductor device 100 having an oxidized termination region 105 with one or more capacitively segmented trench structures 805A or stripe trench structures 805B. The semiconductor device 100 includes a voltage termination structure having a continuous termination region composed entirely of an electrically insulating layer extending a finite distance vertically from the device surface. In one embodiment, the semiconductor device 100 includes an active region 110 including a plurality of capacitively coupled active trenches 310 arranged parallel to each other along a first direction, and a voltage termination structure 105 including a continuous termination region composed entirely of an electrically insulating layer extending a finite distance vertically from the device surface. In one embodiment, the insulating layer includes deposited silicon dioxide. In another embodiment, the insulating layer includes thermally grown silicon dioxide. In another embodiment, the insulating layer includes deposited silicon nitride. In another embodiment, the insulating layer includes thermally grown silicon nitride.

FIG. 9A is an illustration showing an exploded top view of an embodiment of the semiconductor device 100 having termination trenches 905A located in the drain termination region 105 that are perpendicular to the active trenches 910A located in the active region 110. Each of the termination trenches 905A contain polysilicon field plates, which can be floating. In one embodiment, the semiconductor device 100 has an active region 110, which includes a plurality of capacitively coupled active trenches 910A arranged parallel to each other along a first direction, and a voltage termination structure 105, which includes at least one capacitively coupled termination trench 905A arranged along a second direction. The second direction is perpendicular to the first direction. The active trenches 910A and the termination trenches 905A can be substantially similar.

The polysilicon field plates, which are located inside the termination trenches 905A, are coupled to polysilicon connections 905B, which run perpendicular to the termination trenches 905B. The polysilicon connections 905B run parallel to the active trenches 910A. Each of the polysilicon connections 905B can overlay all the termination trenches 905A, in a perpendicular direction, and make contact with at least one polysilicon field plate disposed in a termination trench 905A. Alternatively, each of the polysilicon connections 905B can overlay at least one of the termination trenches 905A, in a perpendicular direction, and make contact with at least one polysilicon field plate disposed in an overlaid termination trench 905A. In one embodiment, each polysilicon connections 905B is set to make contact with polysilicon field plates located in only a single termination trench 905A. In another embodiment, each polysilicon connections 905B is set to make contact with polysilicon field plates located in only a single termination trench 905A and such that the first polysilicon connection 905B disposed closest to the drain (120A, 120B) makes contact with the polysilicon field plates located in the first termination trench 905A disposed closest to the drain region (120A, 120B). Consecutive polysilicon connections 905B can further make contact with polysilicon field plates located in consecutive termination trenches 905A, so that the second polysilicon connection 905B disposed away from the drain region (120A, 120B) makes contact with the polysilicon field plates located in the second termination trench 905A disposed away from the drain region (120A, 120B); the third polysilicon connection 905B disposed away from the drain region (120A, 120B) makes contact with the polysilicon field plates located in the third termination trench 905A disposed away from the drain region (120A, 120B); etc.

In the embodiment illustrated in FIG. 9A, polysilicon connections 905B are equally spaced apart. In the embodiment where the termination trenches 905A are also equally spaced apart, the points of contact between the polysilicon connections 905B and the polysilicon field plates in the termination trenches 905A form a line. In the embodiment where the termination trenches 905A are not equally spaced apart, the points of contact between the polysilicon connections 905B and the polysilicon field plates in the termination trenches 905A form a curve rather than a line.

FIG. 9B, which is similar to FIG. 9A, is an illustration showing a semiconductor device 100 having polysilicon connections 905B that are spaced apart variably. As with the semiconductor device illustrated in FIG. 9A, the semiconductor device shown in FIG. 9B has termination trenches 905A located in the drain termination region 105 that are perpendicular to the active trenches 910A located in the active region 110. In the embodiment illustrated in FIG. 9B, the spacing between the polysilicon connections 905B becomes wider the closer the polysilicon connections 905B are to the drain region (120A, 120B) finger tip. In the embodiment where the termination trenches 905A are equally spaced apart, the points of contact between the polysilicon connections 905B and the polysilicon field plates in the termination trenches 905A form a curve. In the embodiment where the termination trenches 905A are not equally spaced apart, the points of contact between the polysilicon connections 905B and the polysilicon field plates in the termination trenches 905A also form a curve, which can be a line in some configurations.

In an embodiment, the at least one termination pitch (termination trench 905A+spacing between termination trenches 905A) includes silicon regions that are either wider or narrower laterally from capacitor to capacitor than those used for conduction in the active device 110 drift regions. The at least one termination pitch can also include first silicon regions that are half the width from capacitor to capacitor than second silicon regions used for conduction in the active device 110 drift regions. The at least one termination pitch can include first silicon regions that are shorter or longer in a direction parallel to the termination trenches than second silicon regions used for conduction in the active device 110 drift regions. The at least one termination pitch can also include first silicon regions that are twice as long in a direction parallel to the termination trenches than second silicon regions used for conduction in the active device 110 drift regions. The at least one termination pitch can further include first silicon regions that are doped differently, either higher or lower, or with a different dopant species, than second silicon regions used for conduction in the active device 110 drift regions.

Although specific embodiments of the invention have been described, various modifications, alterations, alternative constructions, and equivalents are also encompassed within the scope of the invention. The described invention is not restricted to operation within certain specific embodiments, but is free to operate within other embodiments configurations as it should be apparent to those skilled in the art that the scope of the present invention is not limited to the described series of transactions and steps.

The specification and drawings are, accordingly, to be regarded in an illustrative rather than a restrictive sense. It will, however, be evident that additions, subtractions, deletions, and other modifications and changes may be made thereunto without departing from the broader spirit and scope of the invention as set forth in the claim.

What is claimed is:

1. A semiconductor device comprising:
an active region comprising a plurality of capacitively coupled active trenches arranged parallel to each other along a first direction; and
a voltage termination structure comprising at least one capacitively coupled termination trench arranged along a second direction;
wherein the second direction is perpendicular to the first direction.

2. The semiconductor device of claim 1 wherein the at least one termination pitch comprises silicon regions that are either wider or narrower laterally from capacitor to capacitor than those used for conduction in the active device drift regions.

3. The semiconductor device of claim 1 wherein the at least one termination pitch comprises first silicon regions that are half the width from capacitor to capacitor than second silicon regions used for conduction in the active device drift regions.

4. The semiconductor device of claim 1 wherein the at least one termination pitch comprises first silicon regions that are shorter or longer in a direction parallel to the at least one termination trench than second silicon regions used for conduction in the active device drift regions.

5. The semiconductor device of claim 1 wherein the at least one termination pitch comprises first silicon regions that are twice as long in a direction parallel to the at least one termination trench than second silicon regions used for conduction in the active device drift regions.

6. The semiconductor device of claim 1 wherein the at least one termination pitch comprises first silicon regions that are doped differently, either higher or lower, or with a different dopant species, than second silicon regions used for conduction in the active device drift regions.

7. The semiconductor device of claim 1 wherein the termination structure comprises metal field plates disposed at the source side, the drain side, or both sides.

8. The semiconductor device of claim 7 wherein the field plates are fabricated using processes used for forming metal interconnect layers.

9. The semiconductor device of claim 1 further comprising at least one polysilicon connector disposed over at least one field plate wherein:
the at least on field plate is disposed in the termination trench; and
the polysilicon connectors are connected to at least one polysilicon field plate.

10. The semiconductor device of claim 9 wherein the polysilicon connectors are disposed perpendicular to the at least one termination trench and having a spacing separating the adjacent polysilicon connectors that varies with the spacing getting larger as they get closer to the drain side.

11. The semiconductor device of claim 1 wherein the at least one termination pitch comprises a transitional silicon mesa disposed between the termination trenches and the conduction trenches.

12. The semiconductor device of claim 11 wherein the transitional mesa is the same width, wider, or narrower than the conduction mesas.

13. The semiconductor device of claim 1 wherein the termination structure comprises one or more field plates formed by polysilicon, metal, or other conducting material extending from over the conduction trenches to over the termination trenches in a pattern that modifies the electric fields present in the termination trenches.

14. A semiconductor device comprising:
an active region comprising a plurality of capacitively coupled active trenches arranged parallel to each other along a first direction; and
a voltage termination structure comprising at least one capacitively coupled termination trench arranged along a second direction;
wherein the second direction is parallel to the first direction.

15. The semiconductor device of claim 14 wherein the active trenches and the termination trenches are substantially similar.

16. The semiconductor device of claim 14 wherein the at least one termination pitch comprises first silicon regions that are either wider or narrower laterally from capacitor to capacitor than second silicon regions used for conduction in the active device drift regions.

17. The semiconductor device of claim 14 wherein the at least one termination pitch comprises first silicon regions that are half the width from capacitor to capacitor than second silicon regions used for conduction in the active device drift regions.

18. The semiconductor device of claim 14 wherein the at least one termination pitch comprises first silicon regions that are shorter or longer in a direction parallel to the at least one termination trench than second silicon regions used for conduction in the active device drift regions.

19. The semiconductor device of claim 14 wherein the at least one termination pitch comprises first silicon regions that are twice as long in a direction parallel to the at least one termination trench than second silicon regions used for conduction in the active device drift regions.

20. The semiconductor device of claim 14 wherein the at least one termination pitch comprises first silicon regions that are doped differently, either higher or lower, or with a different dopant species, than second silicon regions used for conduction in the active device drift regions.

21. The semiconductor device of claim 14 wherein the termination structure comprises metal field plates at the source side, the drain side, or both sides.

22. The semiconductor device of claim 21 wherein the field plates are fabricated by any or all of the process metal interconnect layers.

23. The semiconductor device of claim 14 wherein the at least one termination pitch comprises a transitional silicon mesa between the termination trenches and the conduction trenches.

24. The semiconductor device of claim 23 wherein the transitional mesa is the same width, wider, or narrower than the conduction mesas.

25. The semiconductor device of claim 14 wherein the termination structure comprises one or more field plates formed by polysilicon, metal, or other conducting material extending from over the conduction trenches to over the termination trenches in a pattern that modifies the electric fields present in the termination trenches.

26. A semiconductor device comprising:
an active region comprising a plurality of capacitively coupled active trenches arranged parallel to each other along a first direction; and
a voltage termination structure comprising at least one capacitively segmented trench structure comprising dielectric lined regions filled with conducting material and completely surrounded by a silicon mesa region.

27. The semiconductor device of claim 26 wherein the at least one termination trench comprises a width to length aspect ratio of about one.

28. The semiconductor device of claim 26 wherein the at least one termination trench comprises a width substantially the same, or wider, or narrower than the intrinsic device conduction trenches.

29. The semiconductor device of claim 26 wherein the at least one termination trench shares one or more processing steps with the intrinsic device drain drift region conduction trenches.

30. The semiconductor device of claim 26 wherein the at least one termination pitch comprises first silicon regions doped differently, either higher or lower, or with a different dopant species, than second silicon regions used for conduction in the active device drift regions.

31. The semiconductor device of claim 26 wherein the termination structure comprises metal field plates at the source side, the drain side, or both sides.

32. The semiconductor device of claim 26 wherein the at least one termination pitch comprises a transitional silicon mesa between the termination trenches and the conduction trenches.

33. The semiconductor device of claim 32 wherein the transitional mesa is the same width, wider, or narrower than the conduction mesas.

34. A semiconductor device comprising:
an active region comprising a plurality of capacitively coupled active trenches arranged parallel to each other along a first direction; and
a voltage termination structure comprising a continuous termination region composed entirely of an electrically insulating layer extending a finite distance vertically from the device surface.

35. The semiconductor device of claim 34 wherein the insulating layer comprises deposited silicon dioxide.

36. The semiconductor device of claim 34 wherein the insulating layer comprises thermally grown silicon dioxide.

37. The semiconductor device of claim 34 wherein the insulating layer comprises deposited silicon nitride.

38. The semiconductor device of claim 34 wherein the insulating layer comprises thermally grown silicon nitride.
